(19) United States
(12) Patent Application Publication
(10) Pub. No.: US 2026/0101485 A1
(43) Pub. Date: Apr. 9, 2026

(54) Artificial Intelligence Predictive Liquid Quality System for High-Performance Computing (HPC) Data Center Cooling Loops (AIPWQ)

(71) Applicant: Cedric Daniel Thomas, Greensboro, NC (US)

(72) Inventor: Cedric Daniel Thomas, Greensboro, NC (US)

(21) Appl. No.: 19/405,477

(22) Filed: Dec. 2, 2025

(51) Int. Cl. H05K 7/20

(52) U.S. Cl. CPC H05K 7/20836; H05K 7/20781

(57) ABSTRACT

An automated system for predictive liquid quality management in high-performance computing (HPC) data center cooling infrastructure. The system periodically extracts coolant samples from a liquid loop and performs a series of analyses to detect potential contaminants and degradation factors, including copper ion concentration, dissolved metals, microbial activity, hardness, sulfur compounds and galvanic corrosion indicators. Analytical results are processed by an artificial intelligence module trained on historical coolant chemistry, server workload telemetry and quantifiable coolant loop and datacenter environmental factors to forecast deterioration events and generate alerts and reports for personnel. Frequency of sampling and testing can be adjusted. Based on predictive outcomes, the system generates corrective action recommendations such as filtration scheduling, sterilization, or maintenance alerts, without direct chemical dosing. By isolating liquid quality testing to periodic sampling and predictive analysis, the invention provides a novel approach to maintaining coolant integrity and operational reliability in HPC environments.

Field: This invention relates to liquid cooling systems for high-performance computing (HPC) data centers, and more specifically to automated systems that periodically sample coolant from closed-loop liquid cooling circuits, analyze its quality, and apply artificial intelligence (AI) predictive models to forecast deterioration events and recommend corrective actions.

Background: Liquid cooling systems are increasingly deployed in HPC environments to manage thermal loads from CPUs, GPUs, and other high-density components. Conventional systems rely on continuous inline monitoring or reactive dosing of chemical additives to maintain coolant integrity. These approaches present limitations:
Inline monitoring may miss localized or transient contamination events.
Automated dosing systems, focus on reactive chemical injection rather than predictive analysis.
There is a need for predictive analysis of closed-loop HPC coolant chemistry.

There remains a need for a system that isolates coolant quality testing through periodic sampling, applies predictive AI/ML analysis, and generates actionable recommendations.

### SUMMARY OF THE INVENTION

The invention provides an automated system that periodically extracts coolant samples from a localized coolant liquid loop. The samples undergo a series of analyses to detect contaminants and degradation factors, including copper ion concentration, dissolved metals, microbial activity, hardness, sulfur compounds, and galvanic corrosion indicators. Analytical results are processed by an AI module trained on historical coolant chemistry, server workload telemetry and other coolant loop environmental factors including pressure, temperature and flow to forecast deterioration events.

The system generates alerts and reports for maintenance personnel and provides corrective action recommendations such as filtration scheduling, sterilization, or maintenance interventions. Human intervention is called upon when alerts are generated, and recommendations are given concerning the best course of action. Sampling frequency and testing protocols are adjustable. The invention does not rely on continuous inline monitoring or direct chemical dosing to correct established water quality issues but predicts water quality events as based on test results and analysis as a predictive liquid quality management in HPC environments.

### System Architecture

Sampling Module: Automated equipment extract liquid samples from the liquid coolant loop at scheduled intervals.
Testing Module: Integrated sensors and assays measure copper ion concentration, dissolved metals, microbial activity, hardness, sulfur compounds, galvanic corrosion potential and potential of hydrogen (pH) levels upon sampling. The invention includes storage apparatus for holding reagents or chemicals used to test extracted samples from data center liquid coolant.
AI/ML Module: Predictive models trained on historical coolant chemistry, workload telemetry and other coolant loop environmental factors including pressure, temperature and flow forecast to deterioration events.
Control Interface: Generates alerts, reports, and corrective action recommendations (filtration, dosing, sterilization, maintenance scheduling).

### Operation

Periodic sampling is initiated according to configurable schedules.
Samples are analyzed offline or inline within the testing module.
Results are processed by AI/ML algorithms to predict future deterioration.
Alerts and reports are generated for maintenance personnel.
Corrective recommendations are issued without direct chemical dosing.

### Advantages

Periodic sampling allows for more sophisticated tests than conventional methods
Provides periodic monitoring of HPC-specific contaminants that are present in the data center environment (copper, galvanic corrosion, sulfur, hardness, microbes, pH).
Enhances reliability by forecasting issues before they impact cooling performance.
Adaptable to different coolants (water, glycol blends, dielectric fluids).

### TECHNICAL IMPLEMENTATION

The system is implemented as an integrated module at the coolant distribution unit (CDU), Rack or server level of a high-performance computing (HPC) liquid cooling loop. A sampling subsystem employs automated equipment to periodically divert a small volume of coolant into a dedicated testing chamber. Reagent reservoirs and assay tanks enable chemical, electrochemical, and microbiological analyses to determine copper ion concentration, dissolved metals, microbial activity, hardness, sulfur compounds, pH level and galvanic corrosion indicators. Analytical data is digitized and transmitted to an artificial intelligence engine trained on historical coolant chemistry, workload telemetry and other coolant loop environmental factors including pressure, temperature and flow, which generates predictive models of liquid quality deterioration. The AI engine communicates with a control interface that issues alerts, reports, and corrective action recommendations such as filtration scheduling, sterilization, or maintenance interventions. Sampling frequency and testing protocols are dynamically adjustable based on system load, environmental conditions, or operator input, ensuring adaptive and proactive coolant quality management using artificial intelligence without direct chemical dosing.

### Communication Subsystem

The system includes a communication interface configured to transmit analytical results, predictive forecasts, and corrective action recommendations to maintenance personnel and supervisory control systems. Communication may be implemented via wired Ethernet, fiber optic, or wireless protocols such as Wi-Fi or LoRaWAN, depending on data center infrastructure or any means of communication not yet invented. The interface supports secure data exchange using encryption standards (e.g., TLS/SSL) and may integrate with existing data center management platforms through APIs or any programming interface not yet invented. Alerts and reports are generated in real time and can be delivered to dashboards, email systems, mobile devices or any digital media not yet invented. Based in use case, the communication subsystem also supports bidirectional control, enabling operators to adjust sampling frequency, testing protocols, or corrective action parameters remotely.

### Manufacturing Process

The system is manufactured using assembly techniques that facilitate scalability and maintenance. The sampling module is fabricated from materials suitable for prolonged exposure to liquid coolants. Testing chambers and reagent reservoirs are produced using manufacturing techniques that ensure chemical compatibility and sterility. Sensors and assay components are integrated through standardized mounting interfaces, allowing replacement or upgrade without redesign of the entire system. Analytical data generated by the sampling and testing modules may be processed either locally on embedded hardware or edge computing platforms or transmitted via a communication interface to a remote computer or server for centralized processing and predictive analysis. Quality assurance includes leak testing, calibration of sensors, and validation of AI models against reference datasets. The modular design enables mass production while allowing customization for specific coolant chemistries or data center configurations.

### Parts and Components

The system comprises the following primary components:

### Sampling Module:

Equipment configured to periodically divert coolant from the distribution unit (CDU) or rack loop into a controlled testing chamber.

### Testing Module:

Assay chambers, reagent reservoirs, and integrated sensors capable of performing chemical, electrochemical, microbiological, and physical analyses, including pH, conductivity, dissolved metals, microbial activity, hardness, sulfur compounds, and galvanic corrosion indicators.

### Sensor Array:

Inline or localized sensors configured to measure operational parameters such as pressure, flow rate, and temperature, providing supplemental data to enhance predictive modeling.

### Data Processing Unit:

A computing subsystem configured to process analytical and sensor data either locally on embedded hardware or edge computing platforms, or remotely via transmission to a centralized computer or server for AI/ML-based predictive analysis.

### Artificial Intelligence Module:

Machine learning algorithms trained on historical coolant chemistry, workload telemetry, other data center environmental factors including pressure, temperature and flow data to forecast deterioration events and generate predictive maintenance alerts.

### Control and Communication Interface:

Hardware and software modules for secure data exchange, supporting wired or wireless protocols, encryption standards, and integration with supervisory control systems. Provides bidirectional communication for alerts, reports, and operator adjustments.

### Corrective Action Subsystems (Optional):

Sterilization units (e.g., UV, electrolysis, ozone) and filtration assemblies (e.g., replaceable cartridges, membrane filters) that may be scheduled or activated in data center coolant loop based on predictive outcomes.

### APPLICATIONS

The Artificial Intelligence Predictive Liquid Quality System for High-Performance Computing (AIPWQ) invention is applicable to high-performance computing (HPC) environments, hyperscale data centers, and enterprise facilities utilizing liquid cooling loops for thermal management. By integrating periodic sampling, multi-assay testing, and AI/ML predictive analysis of coolant chemistry, pressure, flow, temperature and workload telemetry, the invention enables proactive identification of corrosion, scaling, microbial growth, and hydraulic anomalies before they compromise system reliability. Beyond HPC, the system may be adapted for industrial process cooling, semiconductor fabrication plants, and other mission-critical operations where liquid quality directly impacts equipment longevity and efficiency. The communication interface allows seamless integration with supervisory control platforms, enabling operators to receive actionable insights and schedule corrective interventions without reliance on direct chemical dosing. In certain examples, the invention supports remote or cloud-based processing, making it suitable for distributed monitoring across geographically diverse facilities.

| | |
|---|---|
| Claims | Independent and dependent claims made for |
| pg. 9 | patent application |
| Abstract | Brief description of invention for searchable |
| pg. 14 | databases |

1. System claim
A system for predictive liquid quality management in a high-performance computing cooling loop comprising:
a sampling module configured to periodically extract coolant samples from the loop;
a testing module configured to perform assays on the samples, the assays including chemical, electrochemical, microbiological, and physical analyses;
a sensor array configured to measure operational parameters including pressure, flow rate, and temperature of the coolant loop;
a data processing unit configured to process analytical and sensor data locally on embedded hardware or edge computing platforms, or remotely via transmission to a centralized computer or server;
an artificial intelligence module trained on historical coolant chemistry, workload telemetry, pressure data, temperature data, and flow data to forecast deterioration events; and
a communication interface configured to generate alerts and corrective action recommendations without direct chemical dosing.

2. The system of claim 1, wherein the artificial intelligence module applies machine learning algorithms to detect anomalies in pressure and flow trends.

3. The system of claim 1, wherein predictive outcomes integrate pressure, temperature and flow data with workload telemetry to improve accuracy of deterioration forecasts.

4. The system of claim 1, wherein the testing module performs assays selected from the group consisting of pH measurement, conductivity analysis, dissolved metal detection, microbial activity assessment, hardness evaluation, sulfur compound detection, and galvanic corrosion analysis.

5. The system of claim 1, wherein the communication interface supports secure data exchange via wired Ethernet, fiber optic, or wireless protocols including Wi-Fi or LoRaWAN.

6. The system of claim 1, wherein the data processing unit transmits analytical results to a remote server for cloud-based artificial intelligence predictive analysis.

7. The system of claim 1, wherein the artificial intelligence module generates maintenance alerts when pressure deviations indicate potential blockages, leaks, or pump degradation.

8. The system of claim 1, wherein flow data is correlated with contaminant analysis to identify localized corrosion or scaling events.

9. Method claim
A method for predictive liquid quality management in a high-performance computing cooling loop comprising the steps of:
periodically extracting coolant samples from the loop;
performing assays on the samples to detect contaminants and chemical properties;
measuring operational parameters including pressure, flow rate, and temperature of the coolant loop;
transmitting analytical and sensor data to a data processing unit;
applying artificial intelligence algorithms trained on historical coolant chemistry, workload telemetry, pressure data, temperature data and flow data to forecast deterioration events; and
generating alerts and corrective action recommendations without direct chemical dosing.

10. The method of claim 9, wherein the assays include detecting pH, conductivity, dissolved metals, microbial activity, hardness, sulfur compounds, and galvanic corrosion indicators.

11. The method of claim 9, further comprising collecting flow data and contaminant analysis to predict localized corrosion or scaling events.

12. The method of claim 9, wherein the artificial intelligence algorithms generate maintenance alerts when pressure deviations indicate potential blockages, leaks, or infrastructure degradation.

13. The method of claim 9, further comprising scheduling sterilization or filtration interventions based on predictive outcomes.

14. The method of claim 9, wherein the transmitting step includes secure communication via Ethernet, fiber optic, or wireless protocols.

15. The method of claim 9, wherein the generating step includes integration with supervisory control platforms via application programming interfaces.

16. Computer-Readable Medium Claim
A non-transitory computer-readable medium storing instructions that, when executed by a processor, cause the processor to:
receive analytical data from coolant assays and sensor measurements including pressure, flow rate, and temperature;
process the data locally or transmit the data to a remote server for centralized analysis;
apply artificial intelligence algorithms trained on historical coolant chemistry, workload telemetry, pressure data, and flow data to forecast deterioration events; and
generate alerts and corrective action recommendations without direct chemical dosing.

17. The computer-readable medium of claim 16, wherein the instructions cause the processor to train artificial intelligence algorithms on historical coolant chemistry, and workload telemetry datasets.

18. The computer-readable medium of claim 16, wherein the instructions cause the processor to apply anomaly detection algorithms to pressure, temperature, flow data and other quantifiable datacenter factors.

19. The computer-readable medium of claim 16, wherein the instructions cause the processor to output predictive outcomes in formats including alerts, dashboards, and application programming interfaces.

20. The computer-readable medium of claim 16, wherein the instructions cause the processor to integrate predictive outcomes with supervisory control platforms for operator decision-making.
